(19) United States
(12) Patent Application Publication
(10) Pub. No.: US 2025/0266410 A1
(43) Pub. Date: Aug. 21, 2025

(54) Stacked Chips System

(71) Applicant: Metaone Corporation, Taipei City (TW)

(72) Inventors: Kuo-Ching CHIANG, Taipei City (TW); Yueh-Feng CHANG, Taipei City (TW)

(21) Appl. No.: 19/043,558

(22) Filed: Feb. 3, 2025

(30) Foreign Application Priority Data
Feb. 17, 2024 (TW) 113105665
Aug. 9, 2024 (TW) 113130040

(51) Int. Cl. H01L 25/16; G02B 6/42; H01L 23/00; H01L 23/15; H01L 23/538; H10B 80/00; H10D 80/30

(52) U.S. Cl. CPC H01L 25/167; G02B 6/4206; H01L 23/15; H01L 23/5385; H10B 80/00; H10D 80/30; H01L 24/16; H01L 2224/16145; H01L 2924/1431; H01L 2924/14361

(57) ABSTRACT

The present invention discloses a stacking system, which includes a system-on-wafer stacked on a photonic base, the photonic base provides a light transmission path, and a power base, which is configured above, below or beside the photon base, wherein the power base includes a power grid, a heat dissipation is stacked on the front of the system-on-wafer.

### TECHNICAL FIELD

The present invention relates to a semiconductor system, more specifically, a semiconductor stacked chips system.

### BACKGROUND

With the advancement of technology, consumer products are developing towards the trends of thinner, lighter and smaller. In order to meet portability requirements, various devices are not only good quality, but also smaller in size and lower in cost. As computing power increases and processes advance to 3 nanometers, the transistor density on a single chip has reached its limit. Consequently, in addition to continuing to improve manufacturing processes, the semiconductor industry is also looking for alternative ways to keep the chip small while maintaining high efficiency. Thus, heterogeneous integration device was announced. The heterogeneous integration refers to two different chips are integrated together through packaging and 3D stacking technologies, for example, a logic chip integrates with a memory.

CoWoS is mainly used in an upgraded semiconductor packaging, so it is also called advanced packaging. Since AI requires a lot of computing, after transistors reach their limits, people's attention turns to the advanced packaging. Following Nvidia's adoption, AMD also introduced CoWoS in latest AI devices. Integrating two chips with different properties is called heterogeneous integration, which in turn leads to 2.5D, 3D packaging technologies and chiplets.

CoW (Chip-on-Wafer) refers to stacking chips, and WoS (Wafer-on-Substrate) refers to stacking chips on a substrate. CoWoS actually means stacking chips and packaging them on a substrate. 3D packaging uses a three-dimensional packaging structure to package multiple chips in the same layer or different layers. CoWoS connects the logic chip and HBM (high bandwidth memory) to an interposer, the chips are coupled through tiny wires in the interposer and connected to the substrate by through silicon via (TSV), and followed by connecting an external circuit through metal balls.

The trend of high-end chips is to stack multiple chiplets and memory together. However, under the demand for high-speed computing, the speed of electronic transmission is still not fast enough. No matter which one of the above methods is used, it cannot meet the demand for AI ultra-high-speed computing. What is required is to improve the packing system.

### SUMMARY OF THE INVENTION

In one aspect, the present invention discloses a stacking system comprising a system-on-wafer, a high-bandwidth memory and a logic chip are formed on the front side of the system-on-wafer. The system-on-wafer is stacked over a photonic base, namely, the photonic base is formed at the rear side of the system-on-wafer to provide optical transmission paths. A power base is arranged above, below or beside the photonic base. The photonic base comprises a silicon wafer or a glass base; wherein the power base includes a power grid formed thereon. A heat dissipation system is stacked on the front side of the system-on-wafer, wherein the heat dissipation system includes a liquid heat dissipation system.

The present invention provides a wafer-level stacking system, which includes a system-on-wafer having a logic device formed on the front side. A photonic base is arranged on the back side of the system-on-wafer to provide optical transmission paths; and a power base is arranged above, below or beside the photonic base.

The present invention provides a stacking system, which includes a system-on-wafer, wherein a high-bandwidth memory and a logic chip are formed on the front side of the system-on-wafer. A photonic base is formed at the back side of the system-on-wafer to provide optical transmission paths. A heat dissipation system is configurated at the front side of the system-on-wafer.

The photonic base includes a silicon or glass material, and the power base includes a power grid formed by nanoimprinting. A meta lens is configurated corresponding to the photonic base, and it is fabricated by nanoimprinting. In one embodiment, a panel-level system replaces the wafer-level system, and the system-on-panel takes place the on-wafer system.

In another aspect of the present invention, an electronic signal substrate is stacked on an optical signal substrate, the optical signal substrate comprises at least one through hole, a cladding layer is formed on the side wall of the through hole. A core is filled within the through hole, and adjacent to the cladding layer, wherein the refractive index of the core is greater than the refractive index of the cladding layer. The laser or diode light source is configurated on or under the substrate, corresponding to at least one through hole. An electrical interposer is formed adjacent to the side or is formed on an optical interposer, wherein the electrical interposer comprises a plurality of conductive through holes.

According to another aspect of the present invention, a hybrid interposer comprises an electrical interposer including a plurality of electrical through-holes; and an optical interposer is located below or beside the electrical interposer. Alternatively, the present invention discloses a hybrid interposer comprising an electrical interposer including a plurality of electrical through-holes, an optical interposer layer is located below or beside the electrical interposer, wherein the optical interposer comprises a plurality of optical waveguides, a logic chip is located over the electrical interposer and/or the optical interposer.

The optical interposer or the hybrid interposer can be applied to the signal transmission layer or structure inside the chip, or applied to the interposer outside the advanced chip packaging. Therefore, the interposer of the present invention refers to the “interposer” for an advanced package, or the interlayer or structure inside the chip. The optical interposer refers to the structure, substrate, and dielectric layer that have optical signal transmission paths, and the electrical interposer refers to the structure, substrate, and dielectric layer that have electrical signal transmission paths.

### BRIEF DESCRIPTION OF THE DRAWINGS

FIG. 1 shows a functional diagram according to the present invention.

FIG. 2 shows a diagram of a light interposer according to the present invention.

FIG. 3 shows a diagram of hybrid stacking structure of the present invention.

FIG. 4 shows steps of forming the wave-guide of the present invention.

FIG. 5 shows a diagram of hybrid stacking structure of the present invention.

FIG. 6 shows a diagram of hybrid stacking structure of the present invention.

FIG. 7 shows a resonator of the present invention.

FIG. 8 shows a spiral resonator of the present invention.

FIG. 9 shows a pillar resonator of the present invention.

FIG. 10 shows a wafer-level stacked system of the present invention.

FIG. 11 shows a wafer-level stacked system and the power base of the present invention.

### DETAILED DESCRIPTION

Some preferred embodiments of the present invention will now be described in greater detail. However, it should be recognized that the preferred embodiments of the present invention are provided for illustration rather than limiting the present invention. In addition, the present invention can be practiced in a wide range of other embodiments besides those explicitly described, and the scope of the present invention is not expressly limited except as specified in the accompanying claims.

Generally, computer/server employs CPU for computing, typically, the CPU excels in logical and floating-point calculations. It is serious challenge to the CPU-based servers while introducing AI, IOT and big data cloud computing. Under such circumstance, it is necessary to improve the data processing capabilities of the servers. GPU involves parallel computing, thus, AI servers employ GPU. The present invention may be applied to the signal transmission layer or structure inside the chip, or applied to the interposer outside the chip. Therefore, the interposer of the present invention refers to both above cases.

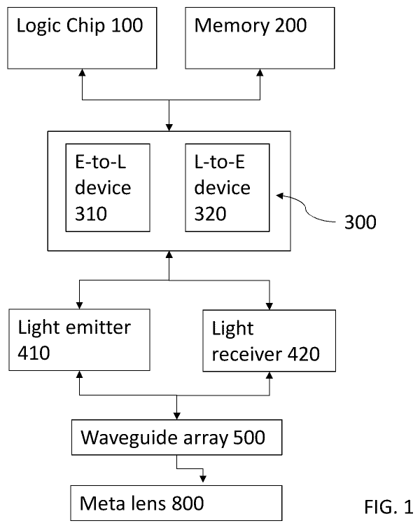

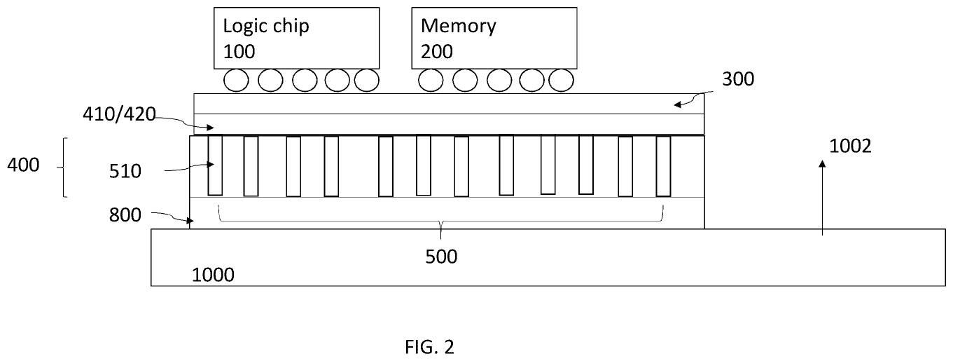

Referring to FIG. 1 and FIG. 2, the present invention includes at least one logic chip 100, such as a GPU and a CPU. The logic chip 100 can be configured in, for example, a mobile phone, a computer, an AI server, a vehicle on-board computer, a mining device, an unmanned vehicle or a game console. Traditional servers use central processing units as the main computing power. AI servers generally refer to the servers that use heterogeneous architectures. The logic chip 100 of the present invention can be selected from any combination of the following: CPU, GPU, NPU, FPGA, TPU, ASIC, etc. Multiple chips are packaged in the same layer or different layers, for example, a logic chip 100 and a memory 200, such as a high-bandwidth memory, are coupled to an interposer 400, and the electronic signals of different chips are coupled through tiny conductive wires in the interposer. At the same time, the lower substrate 1000 is connected by the through silicon via (TSV), and followed by connecting to an external circuit through the metal ball.

The logic chip 100 has an electronic signal transmission mechanism, and the logic chip 100 is coupled to the signal conversion element 300. The signal conversion element 300 is used for converting optical (light) signal into electronic signal and vice versa. The memory 200, such as HBM, is coupled to the signal conversion device 300. The signal conversion element 300 is, for example, an optical transceiver, which is useful for converting signals between electronic signals and optical signals. The optical interposer 400 may include an optical layer, which includes a plurality of optical waveguides 510. The light emitter 410, the light receiver 420 and the signal conversion element 300 are stacked on the interposer 400. In one embodiment, the optical medium may be the interposer 400 which includes at least one optical transmission path, such as an optical waveguide 510.

The light emitter 410/the light receiver 420 are coupled to the signal conversion element 300. The signal conversion element 300 includes an electronic-to-light conversion element 310 and a light-to-electronic conversion element 320, which are coupled to the light emitter 410/the light receiver 420, respectively. For example, after the electronic signal is converted to the light signal, it can be transmitted by a laser array, for example, a vertical cavity surface-emitting laser (VCSEL). The waveguide array 500 is coupled to the light emitter 410/the light receiver 420 to transmit the light signal.

Referring to FIG. 2, the waveguide array 500 is disposed on a substrate 1000. The substrate 1000 is, for example, a PCB, a silicon substrate or glass, the substrate 1000 includes a circuit and an optical receiver formed thereon for receiving the signals transmitted from the waveguide array 500 or it has a light emitter to transmit signal to the logic chip 100 or the memory chip 200 through the waveguide array 500. The waveguide array 500 is formed in an optical (light) interposer 400. In optics, controlling the refractive index may control the direction of light. Total internal reflection (TIR) is the phenomenon in which waves arriving at the interface from one medium to another are not refracted into the second medium. It occurs when the second medium has a lower refractive index than the first, and the waves are incident at a sufficiently oblique angle on the interface. Typically, the core has a higher refractive index than the cladding. The waveguide array 500 may be a vertical waveguide array. The chip and optical path are designed through simulation software, for example, Apollo, BBV, R-Soft, Optiwave, etc.

Light speed is higher than the electronic speed. In one embodiment, the present invention includes an optical medium. Referring to FIG. 2, the waveguide array 500 includes a plurality of vertical optical waveguides 510 which are substantially parallel to a vertical normal line 1002 of the substrate 1000. In FIG. 2, the waveguide array 500 includes vertical optical waveguides to transmit the optical signals to the substrate 1000 having an optical connector and an optical fiber. The substrate 1000 is, for example, a PCB, a silicon substrate, glass or other intermediate layers. A meta lens 800 is configured to the optical waveguides 510.

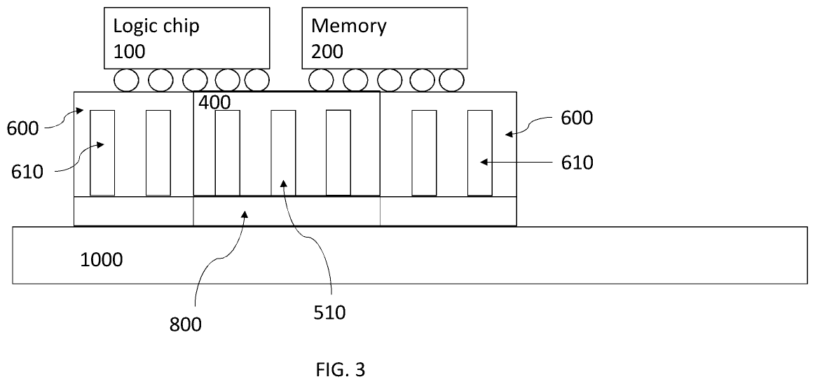

FIG. 3 shows a hybrid interposer embodiment, in which a waveguide array 500 is disposed on the substrate 1000 having a circuit and an optical receiver for receiving light transmitted from the waveguide array 500; or/and a light emitter for emitting optical (light) signals to the logic chip 100 or the memory chip 200 through the waveguide array 500. The logic chip 100 and the memory chip 200 typically include a through silicon via (TSV) for vertically transmitting electronic signals. The hybrid interposer includes an optical (light) interposer 400 and an electronic interposer 600 to transmit optical and electronic signals, respectively. The electronic interposer 600 may include multiple layers of horizontal and vertical conductive lines, and vertical through silicon vias (TSVs) 610. Heterogeneous integration improves system performance and provides high-density interconnects with sub-micron line width and spacing. Since not all signal transmissions must rely on optical waveguides, the present invention integrates optical and electronic signals, both interposers provide a reliable solution based on transmission requirements. For example, if high-bandwidth transmission is required, the optical interposer 400 is used. The hybrid interposer which is consisted of the optical interposer 400 and the electronic interposer 600 is stacked on the substrate 1000. The two interposers can be formed on the same substrate or separated substrates, followed by integrating them together. At least one chip is stacked on the hybrid interposer. The chip may be the logic chip 100 and/or the memory chip 200. The meta lens 800 is configurated to the optical waveguide 510.

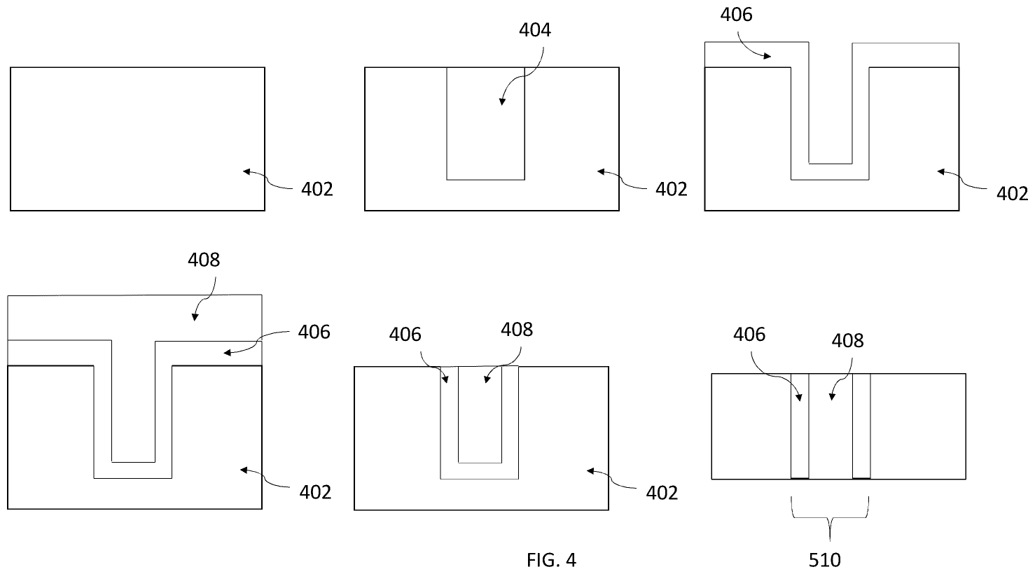

FIG. 4 shows a process for manufacturing the optical waveguide. A substrate 402 made of glass or silicon is provided. A hole 404 is formed on the substrate 402, it may penetrate (or not penetrate) the substrate 402. This embodiment shows that the substrate 400 is not penetrated by the hole 404. The hole 404 can be formed in the substrate 402 by using lithography and reactive ion etching (RIE). Then, a cladding layer 406 is deposited over the hole 404. The material of the cladding layer 406 may be silicon oxide or silicon nitride. A core 408 is deposited on the cladding layer 406. The material of the core 408 may be a polycrystalline silicon layer or a non-crystalline silicon layer. In one case, the crystalline silicon layer is formed so that the refractive index of the waveguide core 408 is greater than that of the cladding layer 406. As an example, the refractive index of silicon dioxide is 1.46, and the refractive index of silicon is 3.7. Silicon nitride is deposited by plasma enhanced chemical vapor deposition (PECVD) and its refractive index (n) ranges from 1.78 to 2.85. In another embodiment, silicon oxide is used as the cladding layer of the waveguide, and silicon nitride is used as the core 408 of the waveguide. A polymer, such as photoresist, may also be used to fill the hole 404 as the waveguide cladding layer 406. An exposure and other steps may be required to cure the photoresist. If polysilicon is used as the core 408 of the waveguide, it can be formed on the substrate with the through silicon via (TSV) process in one identical process, it improves process integration. If the hole is drilled in the base of the glass, laser drilling might be used to form a through glass via (TGV).

Silicon dioxide can be deposited by chemical vapor deposition (CVD) process. Chemical vapor deposition undergoes a chemical reaction in the gas and is deposited onto the silicon wafer to form a low refractive index film. The core 408 is made of high refractive index silicon, polymer or nitride oxide.

Subsequently, a polishing method, such as chemical mechanical polishing, is used to remove portion of the core 408 material, such as polycrystalline silicon, over the surface of the substrate. A portion of the waveguide cladding layer 406 material, such as silicon dioxide, is removed from the substrate. If necessary, the back side of the substrate is grinded to a desired thickness to form the vertical optical waveguides 510. In one embodiment, the front side and the rear side of the substrate is grinded simultaneously to improve the throughput.

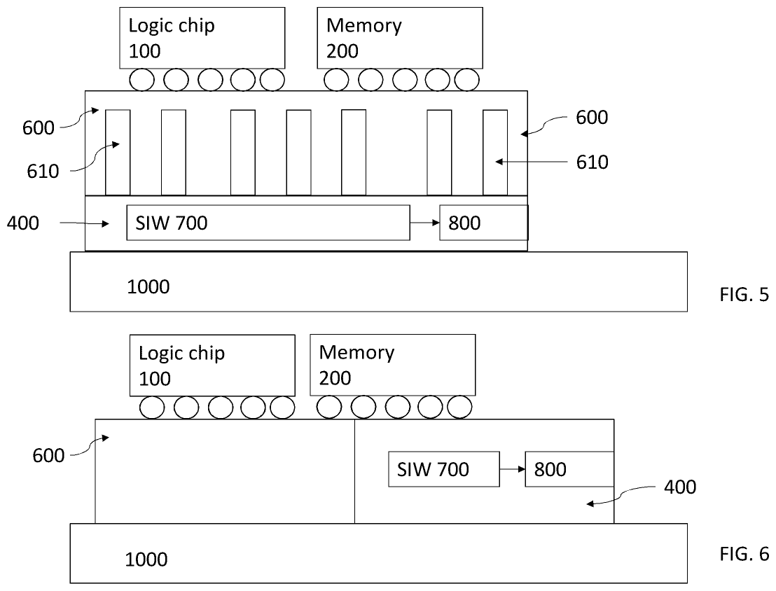

In an alternative embodiment, referring to FIG. 5, the waveguide is formed in the optical interposer 400, for example, a substrate-integrated waveguide (SIW) 700 is formed within the optical interposer 400 which is formed on the substrate 1000. The substrate-integrated waveguide 700 is densely arranged to connect the metallized pillars or perforations for connecting the substrate. The waveguides are formed of a perforated grid and could be mass-production by through-hole technology. If the propagation direction is horizontal, it is usually perpendicular to the normal line of the substrate 1000, the meta lens 800 is configurated corresponding to the waveguides, for example, the substrate-integrated waveguide 700.

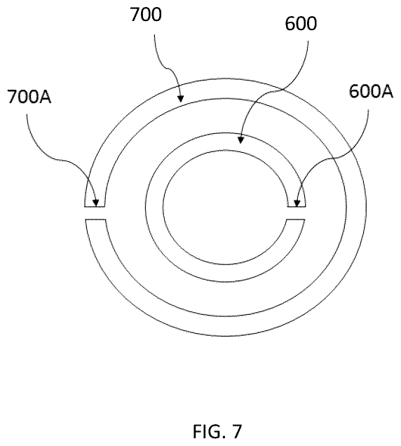

The electronic interposer 600 is stacked over the optical interposer 400 having waveguides for transmitting electronic signal, at least one chip is stacked on the electronic interposer 600. The chip includes the logic chip 100 and/or the memory chip 200. In another embodiment, the interposer 600 and the optical interposer 400 are integrated side-by-side, and both are stacked on the substrate 1000. At least one chip is stacked on the interposer 600 and the substrate integrated waveguide 700; the meta lens 800 corresponds to the waveguides 700. Turing to FIG. 6, the through-holes (silicon through-holes or glass through-holes) in FIG. 5 and FIG. 6 are formed in the dielectric material which includes silicon, glass, polymer, etc., the waveguide material is then refilled in the through-holes (such as FIG. 4). The optical waveguides is therefore achieved. In one embodiment, the substrate for transmitting electrical signals is stacked on another substrate for transmitting optical signals.

The planar optical waveguide chip can be introduced in the embodiments of FIG. 5 and FIG. 6. The substrate of the planar optical waveguide chip includes a silicon wafer. During the device manufacturing stage, the wafer is etched, cut, polished, and so on. In PLC (Planar Lightwave Circuit), the refractive index control element can be made of silicon dioxide, silicon on insulator (SOI), lithium niobate (LiNbO3) or polymer materials. Silicon dioxide is preferred due to good material stability, easy control of refractive index and thickness.

Optical waveguides have different manufacturing processes depending on the material. The silicon dioxide is one of the material candidates. The manufacturing process of the planar optical waveguides is divided into two types: one is chemical vapor deposition (CVD)/with reactive ion etching (RIE) and the other refers to flame hydrolysis deposition (FHD)/with ion etching. The method of forming PLC using CVD involves chemical reaction in gas, and followed by depositing a photoresist on the CVD layer. The part of the CVD layer is subsequently etched by ion etching, and thereafter the cladding layer is deposited to form the waveguide optical paths. The flame hydrolysis deposition (FHD) method uses flame to burn silicon compounds and water vapor. After the reaction, two silicon dioxide films with high and low refractive indexes are formed on the silicon substrate. Then, ion etching is performed to form the required waveguide optical path, a low-refractive index cladding layer is then applied.

The optical fiber of the substrate 1000 may be coupled to the optical waveguide. The optical fiber connection on the substrate could be implemented by laser welding, UV glue or flip-chip bonding to fix the optical fiber array. Optical waveguides can be used to develop different optical communication components, which include, but not limited to, multiplexers/demultiplexers, splitters/couplers, etc. In terms of multiplexers/demultiplexers, arrayed waveguide grating (AWG) chip can be made and it is suitable for DWDM. Secondly, in terms of integrated components, the flip-chip technology can be used to integrate laser diodes, AWG and VOA (variable optical attenuators) into a single component.

In an embodiment, the meta lens 800 is arranged corresponding to the optical waveguide 510 to enhance the electromagnetic waves. Light is composed of electric and magnetic fields. The interaction between traditional lenses (or other natural materials) and light depends majorly on the interaction with electric fields. The magnetic interaction in traditional lens materials is basically zero, which leads to common optical constraints, such as diffraction limitations. Negative refractive index media may overcome this limitation. In 1995, Guerra produced a diffraction grating in silicon with 50 nm lines and spaces which is illuminated with diffraction-born evanescent waves from its transparent replica. Super-resolution is observed with a microscope having an incident illumination of 650 nm in air. Please refer to: Appl. Phys. Lett. 66, 3555-3557 (1995). In 2002, Guerra et al published subwavelength nano-optics for optical data storage at densities well above the diffraction limit., refers to: Japanese Journal of Applied Physics. 41 (Part 1, No. 3B): L866-L875. In the visible light band, if a structure or material exhibits magnetism at high frequencies, resulting in strong magnetic coupling. This can produce a negative index of refraction in the optical range.

Research shows that electromagnetic fields can be manipulated, see Pendry, J. B., D. Schurig, and D. R. Smith, “Controlling electromagnetic fields,” Science, Vol. 312, 1780, 2006. The spatial transformations can be applied from optical to all frequencies. As mentioned above, the front lens in the prior art causes divergent light. Therefore, the present invention configures a light bending element, such as a meta lens, at the front end of the lens set to condense the divergent light (electromagnetic waves). Generally, the transmission of light from air into materials follows the right-hand rule, and its refractive index is positive, thus causing light (electromagnetic waves) to diverge. If the medium's permittivity (ε=ε₀εᵣ) or permeability (μ=μ₀μᵣ) is zero (or approaches zero), its refractive index approaches 0, which is a zero-refractive index material. If the medium's permittivity or permeability is negative, it refers to negative refractive index material. The refractive index of the negative-index material for an electromagnetic wave is a negative value over some frequency range. For plane waves propagating in electromagnetic metamaterials, the electric field, magnetic field and wave vector follow a left-hand rule, the reverse of the behavior of conventional optical material. In optics, the refractive index (or refraction index) of an optical medium is a dimensionless number that gives the indication of the light bending ability of that medium. The refractive index can be seen as the factor by which the speed and the wavelength of the radiation are reduced with respect to their vacuum values. The refractive index is proportional to the root of the product of ε and μ. For most materials, the permittivity and permeability are positive values, while the permittivity of plasma is negative, and the permeability of ferrite is negative. In 2009 Plum, E et al. proposed the properties of negative refractive index materials, see Physical Review B. 79 (3): 035407.

At the interface between zero refractive index material and free space, no matter what incident angle the electromagnetic wave is incident on the zero refractive index material (or negative refractive index material), the incident light is bend to nearly parallel to the normal line of the interface. When the negative index of refraction occurs, propagation of the electromagnetic wave is reversed. Resolution below the diffraction limit becomes possible. This is known as subwavelength imaging. The light will refract in the reverse direction (negatively) at the interface between a material with negative refractive index and a material exhibiting conventional positive refractive index. Light incident on the negative refractive index material will bend to the same side as the incident beam, and for Snell's law to hold, the refraction angle should be negative. Negative refractive index or zero refractive index materials can bend the incident light to approximately parallel the normal line of the interface. The present invention takes advantage of this characteristic, it can effectively converge light (electromagnetic waves), thereby improving the directionality and performance of visible light. It refers to optical resonant medium or optical resonant lens. It means that the lens has resonators to bend visible light.

The meta lens (light converging lens) can be understood as a combination of units. Some units are composed of permittivity media, while other units are composed of permeability media; it can also be composed entirely of the two kinds of materials. The resonant size is less than the visible light wavelengths, the composite unit may include the permittivity and the permeability medias. One or both of the negative permeability and negative permittivity media used in the resonance lens medium of the present invention. Examples of unit patterns include a length of wire, a wire with a loop (or multiple loops) along its length, a coil or multiple wires with loops, other examples include resonators based on spiral patterns. In another embodiment, the surface of the meta lens may have a transparent continuous S-shaped pattern.

The resonant unit such as a split ring resonator interacts with electromagnetic waves. In the present invention, the size of the resonant unit needs to be resonantly matched to the wavelength of visible light. Cell sizes smaller than visible light wavelengths, for example, nested circular split ring resonators with an inner radius of about 30 to 40 nanometers which are capable of interaction in the mid-range of the visible spectrum. Resonators can be rectangular, triangular or circular rings. The medium with split ring resonator arrays produces strong magnetic coupling with the electromagnetic field, which is a characteristic that traditional materials do not have. For example, the periodic split ring resonator array produces negative permeability and other effects. Referring to FIG. 7, each individual split ring resonator is composed of a pair of loops 600 and 700. The loops 600 and 700 have slits 600A and 700A at both ends. Loops 600 and 700 are made of non-magnetic metals such as copper and silver, with a small gap between the loops. The rings can be concentric or square, with gaps set as needed, and the magnetic flux penetrating the metal ring will produce a dipole pattern of electromagnetic fields in the ring.

The small gaps between the rings produces large capacitance values which lowers the resonating frequency. Hence the dimensions of the structure are small compared to the resonant wavelength. This results in low radiative losses and very high-quality factors. In one embodiment, the radius of the split ring resonator is related to the wavelength of the electromagnetic wave. The split ring resonators can be created using semiconductor micro-or nano-fabrication techniques, direct laser or electron beam lithography depending on the resolution required. For example, the terahertz band frequency, which is typically defined as 0.1 to 10 THz, is located at the end of the infrared band, just after the end of the microwave band. This corresponds to millimeter and submillimeter wavelengths between 3 mm (EHF band) and 0.03 mm (long wavelength edge of far-infrared light); for microwave radiation, the structure dimensions are of the order of millimeters.

In one embodiment, the split ring resonator is composed of a pair of concentric metal rings formed on the dielectric substrate, with slits 600A, 700A etched on opposite sides, see FIG. 7. It can be implemented by semiconductor photolithography processes, printed circuit processes, or electroplating processes. The material of the ring could be ITO, IZO. The main purpose of the split ring resonator is to produce negative or zero permeability medium (material). When the split ring resonator array is excited by a time-varying magnetic field, the structure behaves like an equivalent permeability medium with negative values. Split ring resonators can be used to increase the transmission distance of near-field waves. The split ring resonators exhibit resonant electric response in addition to resonant magnetic response. The response is averaged over the composite structure when it combined with an array of wires, which results in effective values, including the refractive index. The split ring resonator array layer and the wire array layer can be fabricated on different layers. Similar multiple layers are stacked in sequence, depending on the needs and performance. The two or three-dimensional array can also be fabricated.

As aforementioned, a U-shaped resonator may be used as well. A nanoscale resonator unit has three small metal rods that are physically connected and are configured in a U-shape. The gap at the open end of the U-shape acts as a nanocapacitor. This forms an optical nano-LC resonator that generates local electric and magnetic fields when externally excited. In another embodiment, C-shaped or S-shaped resonators may also be used. Resonators can be stacked in one or more layers; it should be noted that none of the resonators are connected to a power source.

The present invention utilizes negative permeability (or/and negative permittivity) materials to improve performance. The meta lens (or optical resonant lens) 800 configurations have better optical signals. Based on the configurations, the electromagnetic field converges in the near field. Under the phenomenon, the electromagnetic waves are bent and converged by the meta lens 800. Therefore, the present invention has better light convergence effects.

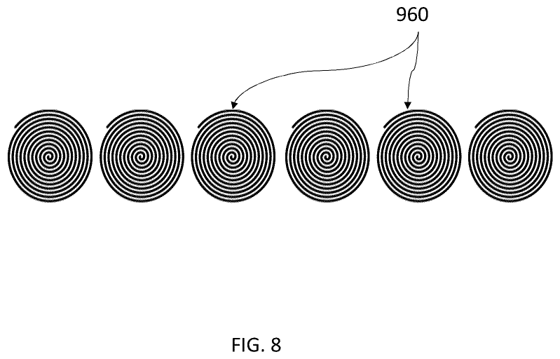

The meta lens 800 includes a plurality of resonators, preferably, the resonators include a spiral coil 960 as shown in FIG. 8. The spiral coil 960 is used as a resonator. The resonator is excited by visible light. In addition, the above-mentioned split ring resonator array may be replaced by the spiral coil 960 array in one embodiment, depending on the requirements.

The resonator array excites due to the electromagnetic field of visible light, thereby changing the refractive index of the transmission medium, forming a zero or negative refractive index medium which enhances the electromagnetic field of the system to overcome limitations, and increase the transmission energy and efficiency. Typically, the visible light determines the power transfer level, efficiency, and overall performance of the system. In one embodiment, the resonator array is fabricated on a glass substrate, for example, repeating periodic resonators are provided on the glass, and a multi-layer resonator array can be fabricated through lamination to produce a two-dimensional or three-dimensional array. In addition to the glass, other material could be used to replace the glass as the substrate, the alternative material includes, but not limited to, plastic, quartz, and sapphire. The resonator may include part or all of straight lines, circles, squares, rectangles, triangles, spirals. In some cases, the patterns may have the gap.

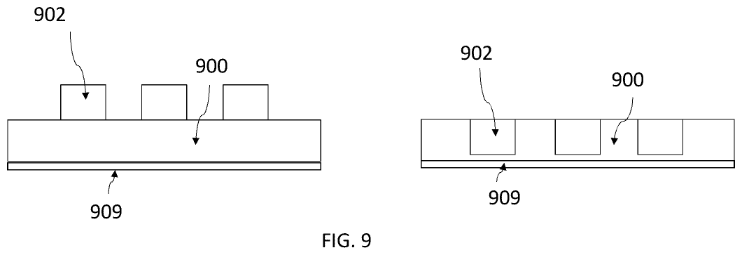

Referring to FIG. 9, the meta lens 800 includes a plurality of nano-resonators 902 formed on a transparent substrate 900. In another embodiment, the nano-resonators 902 are formed in the transparent substrate 900, for example, they are formed in a trench of the transparent substrate 900. The nano-resonators 902 can be conductive pillars, forming an antenna-based resonator which is capable of responsive to the wavelength of incident light. The material of the nano-resonator 902 includes silicon, such as polycrystalline silicon, single crystal silicon or amorphous silicon, which can be doped or undoped silicon; the material of the nano-resonator 902 can be a metal compound, such as titanium dioxide, gallium nitride. An alternative embodiment, the nano-resonator 902 includes metal, such as silver, gold, copper, aluminum, tungsten or the alloys of thereof. Thee nano-resonator 902 material can also be silicon carbide, graphene, carbon nanotubes. The material of the transparent substrate 900 may be plastic, quartz, glass (silicon dioxide), etc. A capacitance is formed between the conductive pillars and the LC oscillation structure is formed. Secondly, the transparent conductive layer 909 is optionally coated on the bottom side of the transparent substrate 900 in the manner of whole surface or in the form of grid. The conductive grid layer 909 is aligned with each resonator 902 to form a capacitive structure with the resonator 902, that is, the resonator 902/transparent substrate 900/conductive layer 909. The conductive pillars and the capacitor structure constitute an LC oscillation structure. The transparent conductive layer 909 may include ITO, ZnO, graphene, carbon nanotubes, etc.

The size of the resonator 902 is related to the resonant frequency, that is, it is dependent on the wavelength of light, and the resonant frequencies generated by light of a specific wavelength are different. In order for the visible light spectrum to excite the resonates appropriately, the resonators have to be responsive to the resonant frequencies. Preferably, the light source of the light emitter 410 is in the infrared spectrum, and the resonant frequency of the present invention responds to the infrared spectrum.

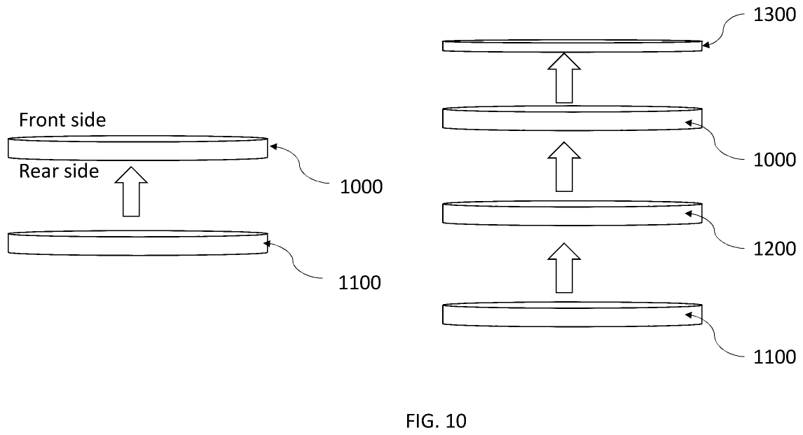

The present invention can also be applied to a system chip, such as the system-on-wafer (SoW) platform, the stacking technology is introduced into the chip-on-wafer (CoW) and the system-on-wafer. For example, the HBM4 stacking involves a 2048-bit interface and is more tightly integrated with logic. By using the wafer-level integration may integrate more logic chips and memory on the front side of the system-on-wafer 1000, thereby providing more computing resources for artificial intelligence clusters. Please refer to FIG. 10, the system-on-wafer 1000 is stacked with a photonic base (or photonic wafer) 1100. If the photonic substrate is made of a silicon wafer or a glass substrate, it is called a silicon photonic base or a glass photonic base. Horizontal and vertical light transmission paths (such as optical waveguides) are fabricated on the wafer. The photonic base 1100 is made of silicon or glass. The photonic base 1100 is stacked under the rear side of the system-on-wafer 1000 to provide optical or light transmission paths.

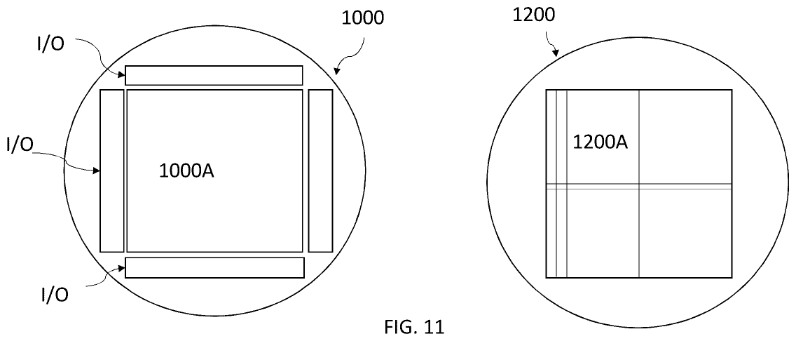

The front side of the system-on-wafer 1000 includes a plurality of I/O regions, a plurality of logic or/and memory blocks 1000A, refer to FIG. 10 and FIG. 11. In another embodiment, a power base (wafer) 1200 is formed between the system-on-wafer 1000 and the photonic base 1100 to provide power to the logic chip, the memory and other components of the system-on-wafer 1000. The power base 1200 includes a power grid 1200A that matches the power input interface of the system-on-wafer 1000, and the figure only shows some vertical and horizontal wires as examples. The power base 1200 may be made of wafer, glass, PCB, or ceramic. In an embodiment, the photonic base 1100 is stacked between the system-on-wafer 1000 and the power base (wafer) 1200. Alternatively, the power base 1200 maybe formed under the photonic base 1100. The areas of the wafers (or bases) 1000, 1100, 1200 may be different. In another embodiment, the photonic base 1100 is located adjacent to the power base 1200, and both are stacked under the rear side of the system-on-wafer 1000. The photonic base 1100, the system-on-wafer 1000 and the power base 1200 are coupled by the methods including one or any combination of vias, through silicon vias or through glass vias. A heat dissipation system 1300, such as a liquid cooling device, may be constructed over the front side of the system-on-wafer 1000. If glass material is used as the substrate, it refers to glass photonic base (or wafer).

Wafer-level packaging (WLP) is a process of packaging and testing directly on the wafer, connecting the multiple chips or components together by a redistribution layer (RDL), followed by protecting them with a polymer. WLP technology eliminates the need for traditional wafer cutting, testing and assembly, it simplifies the process, reduces costs, and enables fast signal transmission from one chip to another with minimal energy consumption. For next-generation servers or data centers, system-level wafers enable 12-inch wafers to accommodate a large number of dice, to provide more computing power and improve performance per watt. The above-mentioned system-on-wafer 1000 can be replaced by a system-on-panel, namely, a panel is used as a substrate to replace the wafer. The system-on-panel reconfigures the wires through the redistribution layer; the photonic base 1100 and the power base 1200 may use the panel as a substrate as well.

The resonant coils of FIG. 7 to FIG. 9 of the present invention have a periodic repeating pattern, which is conducive to manufacture nanoscale structures by using nanoimprint lithography (NIL) process. NIL is a different approach to lithography and NIL does not require the optical system. Canon currently achieved technological breakthroughs down to 5-nanometer scale. Nanoimprinting can be used to rapidly produce nanoscale structures in large quantities. Compared to traditional optical or electron beam lithography, NIL uses a mold to transfer pre-designed patterns and structures directly onto the target material, so large-area nanoscale structures can be manufactured, effectively. First, NIL imprinting creates a pattern on a template, followed by directly imprinting it on the wafer coated with photoresist, the photoresist is filled in the template pattern. The photoresist is cured with ultraviolet light, followed by removing the template to replicate the desired pattern on the wafer. The resonant coils of FIG. 7 to FIG. 9 of the present invention are made by nanoimprinting technology, and the steps include 1. making a template (imprinting mold): usually using an electron beam system to make it on a hard substrate; 2. coating: applying a low viscosity 3. Imprinting and curing: pressing the template onto the resin or photoresist on the substrate (or wafer), and using ultraviolet light to cure the resin; 4. Removing the template: removing the template, leaving the transferred resin structure on the substrate (or wafer). The horizontal and vertical wires of the power transmission grid 1200A can also be manufactured by the nano-imprinting technology, the steps are similar, therefore, the detailed description is omitted.

As will be understood by persons skilled in the art, the foregoing preferred embodiment of the present invention illustrates the present invention rather than limiting the present invention. Having described the invention in connection with a preferred embodiment, modifications will be suggested to those skilled in the art. Thus, the invention is not to be limited to this embodiment, but rather the invention is intended to cover various modifications and similar arrangements included within the spirit and scope of the appended claims, the scope of which should be accorded the broadest interpretation, thereby encompassing all such modifications and similar structures. While the preferred embodiment of the invention has been illustrated and described, it will be appreciated that various changes can be made without departing from the spirit and scope of the invention.

What is claimed is:

1. A stacking chip system comprising:
a first substrate having a vertical waveguide, a horizontal waveguide or the combination thereof to transmit an optical signal; and
a chip formed over said first substrate, wherein said chip includes a logic chip, HBM or the combination thereof, wherein said vertical waveguide or said horizontal waveguide is coupled to said logic chip.

2. The stacking chip system of claim 1, wherein a second substrate having a vertical conductive line, a horizontal conductive line or the combination thereof to transmit an electronic signal, wherein said second substrate is stacked over said first substrate or adjacent to said first substrate.

3. The stacking chip system of claim 2, wherein said second substrate includes an electronic interposer.

4. The stacking chip system of claim 1, wherein said first substrate includes an optical interposer.

5. The stacking chip system of claim 4, wherein a meta lens is configurated to correspond to said vertical waveguide or said horizontal waveguide.

6. The stacking chip system of claim 5, wherein said meta lens includes pillars, spirals, split rings or the combination thereof.

7. The stacking chip system of claim 1, wherein a light emitter or a light receiver is formed between said first substrate and said chip.

8. The stacking chip system of claim 1, wherein a converter is formed between said first substrate and said chip to covert an electronic signal to an optical signal.

9. The stacking chip system of claim 2, wherein said second substrate includes a system-on-panel or a system-on-wafer.

10. The stacking chip system of claim 9, wherein a power base is formed under said system-on-panel or said system-on-wafer, wherein said power base includes a power grid.

11. The stacking chip system of claim 9, wherein a meta lens is configurated to correspond to said vertical waveguide or said horizontal waveguide.

12. A stacking chip system comprising:
a photonic substrate having a vertical waveguide, a horizontal waveguide or the combination thereof to transmit an optical signal;
an electronic substrate having a vertical conductive line, a horizontal conductive line or the combination thereof to transmit an electronic signal;
wherein said electronic substrate is stacked over said photonic substrate or formed adjacent to said photonic substrate; and
a logic chip formed over said electronic substrate, wherein said vertical waveguide or said horizontal waveguide is coupled to said logic chip.

13. The stacking chip system of claim 12, wherein a converter is formed between said photonic substrate and said logic chip.

14. The stacking chip system of claim 13, wherein a light emitter or a light receiver formed between said photonic substrate and said logic chip.

15. The stacking chip system of claim 13, wherein a meta lens is configurated to correspond to said vertical waveguide or said horizontal waveguide.

16. A stacking chip system comprising:
a photonic substrate having a vertical waveguide, a horizontal waveguide or the combination thereof to transmit an optical signal;
an electronic substrate having a vertical conductive line, a horizontal conductive line or the combination thereof to transmit an electronic signal, wherein said electronic substrate is stacked over said photonic substrate; and
a power base located under said electronic substrate to provide a power to said electronic substrate, wherein said power base includes a power grid.

17. The stacking chip system of claim 16, wherein said electronic substrate includes a panel-on-system or a system-on-wafer.

18. The stacking chip system of claim 17, wherein a cooling system is configurated over said system-on-wafer or said panel-on-system.

19. The stacking chip system of claim 16, wherein said photonic substrate includes a glass or silicon base.

20. The stacking chip system of claim 16, wherein a light emitter, a light receiver, a converter or the combination is formed between said photonic substrate and said electronic substrate.
